(19) United States
(12) Patent Application Publication
(10) Pub. No.: US 2021/0272834 A1
(43) Pub. Date: Sep. 2, 2021

(54) ELECTROSTATIC CHUCK MANUFACTURING METHOD, ELECTROSTATIC CHUCK, AND SUBSTRATE PROCESSING APPARATUS

(71) Applicant: TOKYO ELECTRON LIMITED, Tokyo (JP)

(72) Inventor: Masato TAKAYAMA, Miyagi (JP)

(21) Appl. No.: 17/181,661

(22) Filed: Feb. 22, 2021

(30) Foreign Application Priority Data
Mar. 2, 2020 (JP) 2020-035153

(51) Int. Cl. H01L 21/683; H01L 21/67; H01J 37/32; B32B 7/12; B32B 18/00; B32B 37/12

(52) U.S. Cl. CPC H01L 21/6833; H01L 21/67109; H01J 37/32724; B32B 2315/02; B32B 18/00; B32B 37/12; H01J 2237/2007; B32B 7/12

(57) ABSTRACT

A method of manufacturing an electrostatic chuck includes: preparing a first ceramic plate having a first hole formed therein; preparing a second ceramic plate having a second hole formed at a position different from a position of the first hole in a horizontal direction; forming a first slurry layer on the first ceramic plate or the second ceramic plate with a first slurry, the first slurry layer having a flow path formed therein to connect the first hole and the second hole; stacking the first ceramic plate and the second ceramic plate one above the other via the first slurry layer, and bonding the first ceramic plate and the second ceramic plate stacked one above the other via the first slurry layer.

### CROSS-REFERENCE TO RELATED APPLICATION

This application is based upon and claims the benefit of priority from Japanese Patent Application No. 2020-035153, filed on Mar. 2, 2020, the entire contents of which are incorporated herein by reference.

### TECHNICAL FIELD

The present disclosure relates to an electrostatic chuck manufacturing method, an electrostatic chuck, and a substrate processing apparatus.

### BACKGROUND

It is known that in a semiconductor manufacturing process, a heat transfer gas is supplied to a minute space between a substrate and an electrostatic chuck through a through-hole provided in the electrostatic chuck in order to improve the heat transfer property between the substrate and the electrostatic chuck (see, for example, Patent Document 1).

Patent Document 2 discloses an electrostatic chuck including a base body made of ceramic and having a holding surface on the top surface thereof and a heat medium flow path formed therein, and a coating film covering the inner surface of the flow path. This coating film is made of ceramic that is harder than the ceramic of the base body.

### PRIOR ART DOCUMENT

### Patent Document

Patent Document 1: International Publication No. WO2003/046969

Patent Document 2: International Publication No. WO2014/098224

### SUMMARY

According to an aspect of the present disclosure, there is provided a method of manufacturing an electrostatic chuck that includes: preparing a first ceramic plate having a first hole formed therein: preparing a second ceramic plate having a second hole formed at a position different from a position of the first hole in a horizontal direction; forming a first slurry layer on the first ceramic plate or the second ceramic plate with a first slurry, the first slurry layer having a flow path formed therein to connect the first hole and the second hole; stacking the first ceramic plate and the second ceramic plate one above the other via the first slurry layer; and bonding the first ceramic plate and the second ceramic plate stacked one above the other via the first slurry layer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a substrate processing apparatus according to an embodiment.

FIG. 2 is a view illustrating an example of a flow path formed in an electrostatic chuck according to an embodiment.

FIG. 3 is a view illustrating an example of a cross section taken along line A-A in FIG. 2.

FIG. 4 is a flowchart illustrating an example of an electrostatic chuck manufacturing method according to an embodiment.

FIGS. 5A and 5B are views for explaining an example of the electrostatic chuck manufacturing method according to an embodiment.

FIG. 6 is a view for explaining another example of the electrostatic chuck manufacturing method according to an embodiment.

FIG. 7 is a view illustrating another example of a cross section taken along line A-A in FIG. 2.

FIG. 8 is a view illustrating another example of a cross section taken along line A-A in FIG. 2.

FIG. 9 is a flowchart illustrating an example of an electrostatic chuck manufacturing (remanufacturing) method according to an embodiment.

### DETAILED DESCRIPTION

Hereinafter, embodiments of the present disclosure will be described with reference to the accompanying drawings. In the drawings, there may be a case where the same components are designated by like reference numerals with the repeated descriptions thereof omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Substrate Processing Apparatus]

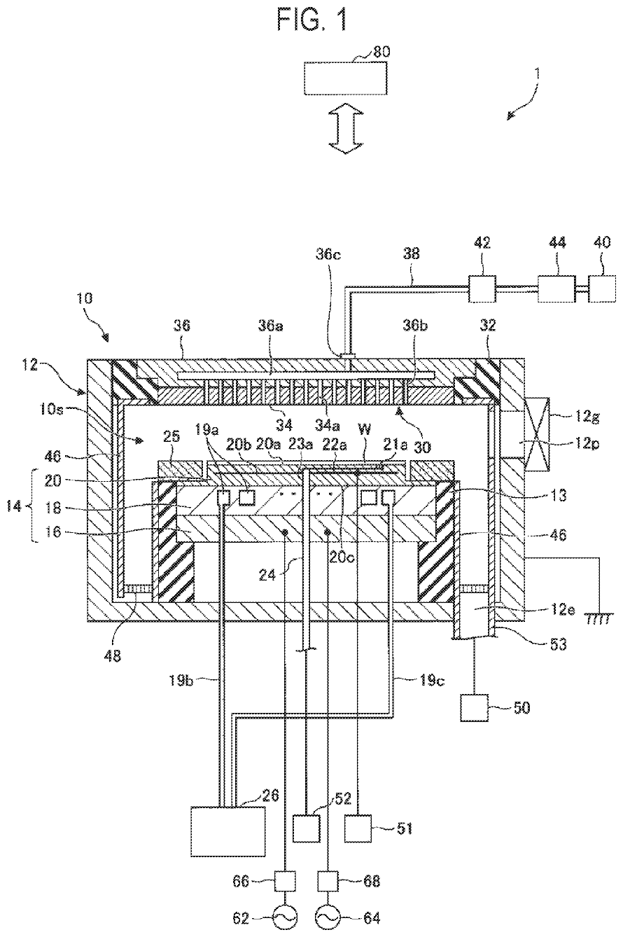

A substrate processing apparatus 1 according to an embodiment will be described with reference to FIG. 1. FIG. 1 is a schematic cross-sectional view illustrating an example of the substrate processing apparatus I according to an embodiment. The substrate processing apparatus I includes a processing container 10. The processing container 10 has a processing space 10s provided therein. The processing container 10 includes a main body 12. The main body 12 has a substantially cylindrical shape. The main body 12 is made of, for example, aluminum. A corrosion-resistant film is formed on an inner wall surface of the main body 12. The film may be made of ceramic such as aluminum oxide, yttrium oxide, or the like.

A passage 12p is formed in the sidewall of the main body 12. A wafer W is transferred between the processing space 10s and the outside of the processing container 10 through the passage 12p. The passage 12p is opened or closed by a gate valve 12g provided along the sidewall of the main body 12.

A support part 13 is provided on a bottom portion of the main body 12. The support part 13 is made of an insulating material. The support part 13 has a substantially cylindrical shape. The support part 13 extends upward from the bottom portion of the main body 12 within the processing space 10s. The support part 13 has a stage 14 provided on a top portion thereof. The stage 14 is configured to support the substrate W thereon in the processing space 10s.

The stage 14 has a base 18 and an electrostatic chuck 20. The stage 14 may further include an electrode plate 16. The electrode plate 16 is made of a conductor such as aluminum and has a substantially disk shape. The base 18 is provided on the electrode plate 16. The base 18 is made of a conductor such as aluminum and has a substantially disk shape. The base 18 is electrically connected to the electrode plate 16.

The electrostatic chuck 20 is placed on a placement surface of the base 18. The substrate W is placed on a placement surface 20a of the electrostatic chuck 20. A main body of the electrostatic chuck 20 has a substantially disk shape. The electrostatic chuck 20 is made of a dielectric material such as ceramic.

An electrode 20b is embedded in the electrostatic chuck 20 in parallel to the placement surface 20a. The electrode 20b is a film-like electrode. The electrode 20b is connected to a DC power supply 51 via a switch (not illustrated). When a DC voltage is applied to the electrode 20b from the DC power supply 51, an electrostatic attractive force is generated between the electrostatic chuck 20 and the substrate W. The substrate W is held on the electrostatic chuck 20 by virtue of the electrostatic attractive force.

The electrostatic chuck 20 has a stepped portion formed around the substrate. An edge ring 25 is arranged on an upper surface of the stepped portion. The edge ring 25 improves the in-plane uniformity of plasma processing on the wafer W. The edge ring 25 may be made of silicon, silicon carbide, quartz, or the like. The edge ring 25 is an example of a ring member located around the substrate, and is also referred to as a focus ring.

A flow path 22a is formed inside the electrostatic chuck 20 and between the placement surface 20a and the electrode 20b. A first hole 21a is formed in the placement surface 20a. In addition, a second hole 23a is formed in a bottom surface 20c of the electrostatic chuck 20. The first hole 21a and the second hole 23a are connected to each other via the flow path 22a. The second hole 23a is connected to a gas source 52 via a gas supply line 24 penetrating the base 18 and the electrode plate 16. The gas source 52 supplies a heat transfer gas (e.g., He gas). The heat transfer gas is supplied between the placement surface 20a of the electrostatic chuck 20 and a rear surface of the substrate W through the gas supply line 24, the second hole 23a, the flow path 22a, and the first hole 21a.

A flow path 19a through which a temperature adjustment medium, such as a coolant, flows is formed inside the base 18. The temperature adjustment medium flows from a chiller unit 26 through an inlet pipe 19b, flows through the flow path 19a, and is returned to the chiller unit 26 through an outlet pipe 19c. As a result, the temperature of the substrate W placed on the electrostatic chuck 20 is adjusted by controlling the heat transfer gas and the temperature adjustment medium.

The substrate processing apparatus 1 further includes a first radio frequency power supply 62 and a second radio frequency power supply 64. The first radio frequency power supply 62 supplies radio frequency power of a first frequency suitable for plasma generation. The first frequency may be a frequency in the range of, for example, 27 MHz to 100 MHz. The first radio frequency power supply 62 is connected to the electrode plate 16 via a matcher 66. The matcher 66 matches an output impedance of the first radio frequency power supply 62 and a load-side (plasma-side) impedance. In addition, the first radio frequency power supply 62 may be connected to an upper electrode 30 via the matcher 66. The first radio frequency power supply 62 constitutes an example of a plasma generation part.

The second radio frequency power supply 64 supplies radio frequency power of a second frequency suitable for attracting ions. The second frequency is a frequency different from the first frequency, and may be a frequency in the range of, for example, 400 kHz to 13.56 MHz. The second radio frequency power supply 64 is connected to the electrode plate 16 via a matcher 68. The matcher 68 matches an output impedance of the second radio frequency power supply 64 and a load-side (plasma-side) impedance.

Plasma may be generated using the radio frequency power of the second frequency instead of the radio frequency power of the first frequency. In this case, the second frequency may be a frequency higher than 13.56 MHz, for example, 40 MHz. In this case, the substrate processing apparatus 1 may not include the first radio frequency power supply 62 and the matcher 66. The second radio frequency power supply 64 constitutes an example of the plasma generation part.

The upper electrode 30 is provided to face the stage 14 and to close an upper opening of the main body 12 of the processing container 10 via an insulating member 32. The upper electrode 30 includes a ceiling plate 34 and a support 36. A bottom surface of the ceiling plate 34 is a bottom surface at the side of the processing space 10s, and defines the processing space 10s. The ceiling plate 34 may be made of a low-resistance conductor or a semiconductor that generates low Joule heat. The ceiling plate 34 has a plurality of gas ejection holes 34a, which penetrate the ceiling plate 34 in a thickness direction of the ceiling plate 34.

The support 36 detachably supports the ceiling plate 34. The support 36 is made of a conductive material such as aluminum. A gas diffusion chamber 36a is provided inside the support 36. The support 36 has a plurality of gas holes 36b extending downward from the gas diffusion chamber 36a. The plurality of gas holes 36b communicate with the plurality of gas ejection holes 34a, respectively. A gas inlet 36c is formed in the support 36. The gas inlet 36c is connected to the gas diffusion chamber 36a. A gas supply pipe 38 is connected to the gas inlet 36c.

A valve group 42, a flow rate controller group 44 and a gas source group 40 are connected to the gas supply pipe 38. The gas source group 40, the valve group 42, the flow rate controller group 44 constitute a gas supply part. The gas source group 40 includes a plurality of gas sources. The valve group 42 includes a plurality of opening/closing valves. The flow rate controller group 44 includes a plurality of flow rate controllers. Each of the flow rate controllers of the flow rate controller group 44 is a mass flow controller or a pressure-controlled flow rate controller. Each of the gas sources of the gas source group 40 is connected to the gas supply pipe 38 via a corresponding opening/closing valve of the valve group 42 and a corresponding flow rate controller of the flow rate controller group 44.

In the substrate processing apparatus 1, a shield 46 is detachably provided along the inner wall surface of the main body 12 and an outer periphery of the support part 13. The shield 46 prevents reaction byproducts from adhering to the main body 12. The shield 46 is constituted by forming a corrosion-resistant film on the surface of a base material made of, for example, aluminum. The corrosion-resistant film may be made of ceramic such as yttrium oxide.

A baffle plate 48 is provided between the support part 13 and the sidewall of the main body 12. The baffle plate 48 is constituted by forming a corrosion-resistant film (a film of yttrium oxide or the like) on the surface of a base material made of, for example, aluminum. A plurality of through-holes are formed in the baffle plate 48. An exhaust port 12e is provided below the baffle plate 48 and in a bottom portion of the main body 12. An exhaust device 50 is connected to the exhaust port 12e via an exhaust pipe 53. The exhaust device 50 includes a pressure adjustment valve and a vacuum pump such as a turbo molecular pump.

Inside the processing container 10, a processing gas is supplied to the processing space 10s. In addition, the radio frequency power of the first frequency and/or the second frequency is applied to the stage 14, whereby a radio frequency electric field is generated between the upper electrode 30 and the base 18, and plasma is generated from the gas by electric discharge.

The substrate processing apparatus 1 may further include a controller 80. The controller 80 may be a computer including a processor, a storage part such as a memory, an input device, a display device, a signal input/output interface, and the like. The controller 80 controls each part of the substrate processing apparatus 1. The controller 80 can enable an operator to perform a command input operation and the like using the input device in order to manage the substrate processing apparatus 1. In addition, the controller 80 controls the display device to visually display the operating situation of the substrate processing apparatus 1. The storage stores a control program and recipe data. The control program is executed by the processor to execute various processes in the substrate processing apparatus 1. The processor executes the control program so as to control each part of the substrate processing apparatus 1 according to the recipe data.

### [Flow Path]

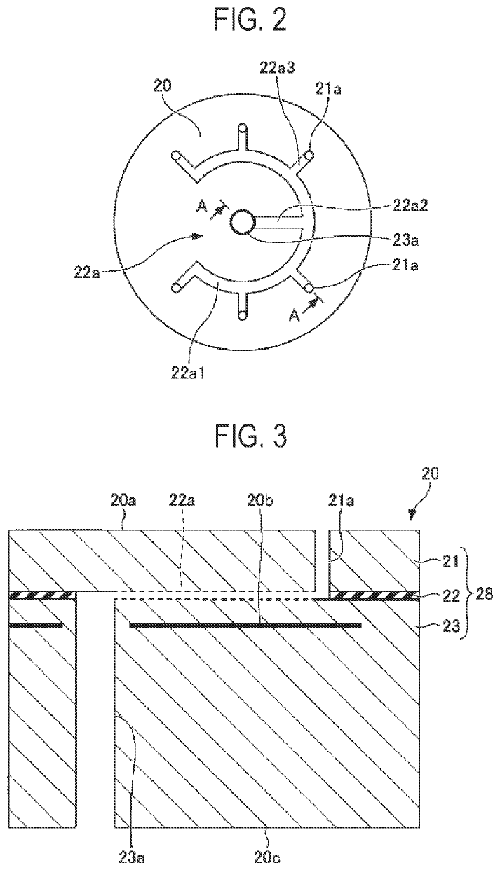

Next, the flow path 22a formed inside the electrostatic chuck 20 and through which the heat transfer gas flows will be described with reference to FIGS. 2 and 3. FIG. 2 is a view illustrating an example of the flow path 22a formed inside the electrostatic chuck 20 according to an embodiment. FIG. 3 is a view showing an example of a cross section taken along line A-A in FIG. 2.

FIG. 2 is a plan view of the flow path 22a formed inside the electrostatic chuck 20. The flow path 22a includes a flow path 22a1 formed in a substantially inverted C shape inside the electrostatic chuck 20, one flow path 22a2 formed to be branched inward from the flow path 22a1, and six flow paths 22a3 formed to be branched outward from the flow path 22a1. The flow path 22a1 is an example of a main flow path, and the flow paths 22a3 are examples of sub-flow paths.

Six first holes 21a are formed concentrically and are connected to the flow path 22a1 via the six flow paths 22a3. However, the number of first holes 21a is not limited thereto. The second hole 23a is formed at substantially the center of the electrostatic chuck 20 and is connected to the flow path 22a1 via the flow path 22a2. An opening of the first hole 21a is smaller than that of the second hole 23a. That is, the area of the opening of the first hole 21a is smaller than the area of the opening of the second hole 23a. The shape of each of the first hole 21a and the second hole 23a may be a circle or a polygon such as a quadrangle.

According to a method of manufacturing the electrostatic chuck 20 according to an embodiment (to be described later), as illustrated in FIG. 3, which is a cross section taken along line A-A in FIG. 2, the electrostatic chuck 20 includes a first ceramic plate 21 having the first holes 21a, and a second ceramic plate 23 having the second hole 23a and laminated on the first ceramic plate 21. Between the first ceramic plate 21 and the second ceramic plate 23 laminated one above the other, the flow path 22a (flow paths 22a1 to 22a3) having a desired height is formed to connect the first holes 21a and the second hole 23a. The flow path 22a is formed at a desired height. For example, the height of the flow path 22a is 5 μm to 30 μm.

The six first holes 21a and the second hole 23a are formed at positions that do not overlap each other in a plan view. That is, the second hole 23a is formed at a position different from those of the six first holes 21a in the horizontal direction. In addition, in the method of manufacturing the electrostatic chuck 20 according to the embodiment, the height of the flow path 22a may be reduced within the range of 5 μm to 30 μm.

Returning to FIG. 2, the width of the flow path 22a1, which is an example of a main flow path, is greater than that of each flow path 22a3, which is an example of a sub-flow path. The gas source 52 is connected to the flow path 22a1 via the gas supply line 24 and the flow path 22a2. As a result, the heat transfer gas supplied from the gas source 52 diffuses in the space of the flow path 22a1 wider than the flow paths 22a3, and is then supplied to the spaces of the flow paths 22a3 narrower than the flow path 22a1. This makes it possible to uniformly introduce the heat transfer gas into the space between the placement surface 20a of the electrostatic chuck 20 and the rear surface of the substrate W.

A slurry layer 22 in which the flow path 22a illustrated in FIG. 3 is formed, is formed by applying slurry between the first ceramic plate 21 and the second ceramic plate 23 when the electrostatic chuck 20 is manufactured. For the sake of convenience in description, the slurry layer 22 is shown to be formed between the first ceramic plate 21 and the second ceramic plate 23 in FIG. 3. However, during the manufacture of the electrostatic chuck 20, when the first ceramic plate 21 and the second ceramic plate 23 are fired in the state of being stacked one above the other via the slurry layer 22, the first ceramic plate 21 and the second ceramic plate 23 are bonded to each other. At this time, the first ceramic plate 21 and the second ceramic plate 23 are integrated with the slurry layer 22. That is, a single ceramic plate 28 is formed by the first ceramic plate 21, the second ceramic plate 23, and the slurry layer 22. Therefore, in the electrostatic chuck 20 after firing, the slurry layer 22 does not exist as a layer, and the space of the flow path 22a1 remains formed inside the ceramic plate 28.

The electrostatic chuck 20 according to the present embodiment is configured such that the heat transfer gas supplied to the second hole 23a formed in the bottom surface of the ceramic plate 28 passes through the flow path 22a provided inside the ceramic plate 28, and is supplied to the rear surface of the substrate W from the first hole 21a. Therefore, compared with the case in which a heat transfer gas supply hole (first hole 21a) provided in the placement surface 20a is used as a through-hole penetrating the ceramic plate 28, a vertical length of the hole can be shortened. As a result, the acceleration of electrons in the first hole 21a is suppressed so that the discharge within the first hole 21a can be suppressed.

In addition, the first hole 21a is provided via the flow path 22a provided inside the ceramic plate 28. Therefore, it is possible to provide the first hole 21a without being restricted by the shape of the flow path 19a provided inside the base 18. Therefore, it becomes easy to provide a plurality of first holes 21a having a small opening. By reducing the size of the opening of the first hole 21a, it is possible to reduce the particular point of the temperature of the substrate W on the placement surface 20a and to improve the controllability of the temperature.

In addition, the second hole 23a is formed at a position different from that of the first hole 21a in the horizontal direction. That is, the first hole 21a and the second hole 23a are not arranged on a straight line. Therefore, for example, during the cleaning of the inside of the processing container 10, when plasma is generated in a state in which no substrate W exists, it is possible to suppress infiltration of the plasma into the second hole 23a and the gas supply line 24. Thus, a member made of a material having low plasma resistance can be arranged inside or on the wall surface of the second hole 23a or the gas supply line 24.

In the example illustrated in FIG. 3, the electrode 20b is provided below the flow path 22a, but may be formed above the flow path 22a. However, since the vertical length of the first hole 21a can be made shorter, it is preferable to provide the electrode 20b below the flow path 22a.

### [Electrostatic Chuck Manufacturing Method]

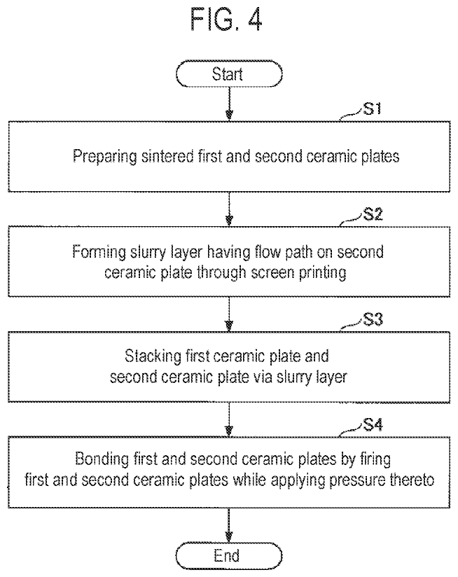

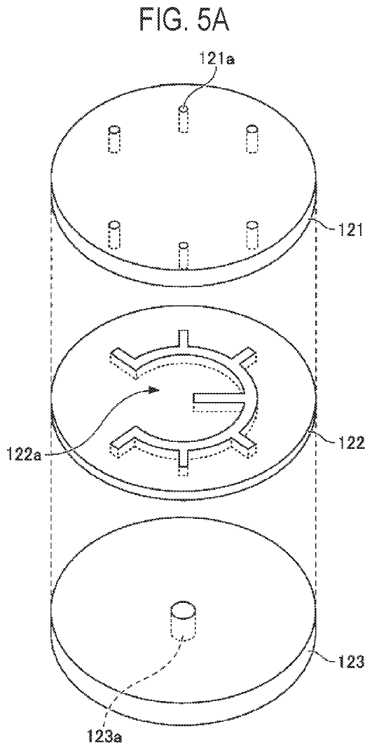

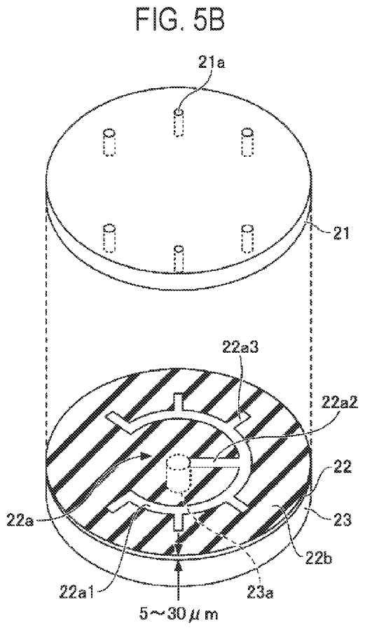

Next, an example of the method of manufacturing the electrostatic chuck 20 will be described with reference to FIGS. 4, 5A, and 5B. FIG. 4 is a flowchart illustrating an example of the method of manufacturing the electrostatic chuck 20 according to an embodiment. FIGS. 5A and 5B are views for explaining an example of the method of manufacturing the electrostatic chuck 20 according to an embodiment.

When the process of FIG. 4 is started, a sintered first ceramic plate 21 having first holes 21a and a sintered second ceramic plate 23 having a second hole 23a are prepared (step S1). The first ceramic plate 21 and the second ceramic plate 23 are preferably sintered bodies of aluminum oxide (Al₂O₃) (hereinafter, also referred to as “alumina”) or sintered bodies of alumina to which silicon carbide (SiC) is added. The first ceramic plate 21 and the second ceramic plate 23 may be made of the same material or different materials.

For example, FIG. 5B illustrates examples of the first ceramic plate 21 and the second ceramic plate 23. The first ceramic plate 21 and the second ceramic plate 23 are disk-shaped plate-like members having the same diameter and the same size. The first ceramic plate 21 has been fired in advance, and six first holes 21a have been formed in the first ceramic plate 21. Similarly, the second ceramic plate 23 has been fired in advance, and one second hole 23a has been formed in the second ceramic plate 23.

In the next step in FIG. 4, a dielectric slurry layer 22 having a flow path 22a is formed on the second ceramic plate 23 through screen printing (step S2). As a result, as illustrated in FIG. 5B, the slurry layer 22 having the flow path 22a (flow paths 22a1, 22a2, and 22a3) are formed on the second ceramic plate 23. Specifically, portions corresponding to the flow paths 22a1, 22a2, and 22a3 are masked, and the slurry 22b is applied to the other portions. As a result, the slurry layer 22, in which the portions corresponding to the flow paths 22a1, 22a2, and 22a3 become spaces, is formed on the second ceramic plate 23.

The slurry 22b to be applied to form the slurry layer 22 is obtained by mixing (dispersing) alumina powder or alumina powder to which silicon carbide is added with a solvent, and is also referred to as a paste. The solvent is a fluorine-based or phenol-based solution, and alumina powder or the like is mixed with this solution. In step S2, the slurry layer 22 may be formed on the surface of the first ceramic plate 21.

In the next step in FIG. 4, the first ceramic plate 21 and the second ceramic plate 23 are stacked one above the other via the slurry layer 22 (step S3). As a result, the first ceramic plate 21 and the second ceramic plate 23 are stacked one above the other, with the slurry layer 22 sandwiched therebetween.

In the next step in FIG. 4, firing is performed while applying pressure in the vertical direction so that the first ceramic plate 21 and the second ceramic plate 23 stacked one above the other via the slurry layer 22 are bonded to each other (step S4), and this process is completed.

In the method of manufacturing the electrostatic chuck 20, the first ceramic plate 21 and the second ceramic plate 23 are tired in the state of being stacked one above the other via the slurry layer 22 so that the first ceramic plate 21 and the second ceramic plate 23 are bonded to each other. As a result, the first ceramic plate 21, the slurry layer 22, and the second ceramic plate 23 are integrated into the ceramic plate 28, and the slurry layer 22 disappears. As a result, the flow path 22a is formed inside the integrated ceramic plate 28. Since the slurry layer 22 is a paste, the flow path 22a may be formed at a height of about 5 μm to 30 μm. Since the flow path 22a can be thinly formed in this way, the vertical length of the first hole 21a can be shortened.

FIG. 5A is a view illustrating an example of an electrostatic chuck manufacturing method according to a comparative example in which a green sheet obtained by press-forming and solidifying a slurry is used.

In the example of FIG. 5A, a green sheet 121 serving as an upper plate, a green sheet 122 in which the flow path 122a is formed, and a green sheet 123 serving as a lower plate are stacked one above another. Then, a slurry is applied between the green sheets 121, 122, and 123 which are stacked one above another, and then firing is performed.

Since the green sheets 121, 122, and 123 illustrated in FIG. 5A are sheets before being subjected to firing, they are softer than the first ceramic plate 21 and the second ceramic plate 23 after firing. Therefore, in the case in which the green sheets are used, when the green sheets are fired while being pressurized as in the method of manufacturing the electrostatic chuck 20 according to the embodiment, the green sheets 121, 122, and 123 may be deformed. Therefore, it is difficult to fire the green sheets while applying pressure thereto. In addition, since the green sheet 122 in which the flow path 122a is formed is a sheet independent of the other green sheets 121 and 123, the green sheet 122 needs to have a certain thickness. As a result, it is difficult to form the flow path 122a of about 5 μm to 30 μm as in the present embodiment.

In contrast, in the method of manufacturing the electrostatic chuck 20 according to the present embodiment, firing is performed after the slurry layer 22 having a thickness of about 5 μm to 30 μm is applied between the first ceramic plate 21 and the second ceramic plate 23. At this time, since the first ceramic plate 21 and the second ceramic plate 23 have been fired in advance, they have higher strength than those of the green sheets. Therefore, even if pressure is applied to the first ceramic plate 21 and the second ceramic plate 23 during firing, deformation does not occur. Accordingly, it is possible to press and solidify the first ceramic plate 21 and the second ceramic plate 23 during firing.

According to the method of manufacturing the electrostatic chuck 20 of the embodiment, the vertical length of the first holes 21a can be shortened. As a result, it is possible to prevent abnormal discharge from occurring in or near the first holes 21a.

In some embodiments, the electrode 20b may be formed in advance on the first ceramic plate 21 or the second ceramic plate 23 prepared in step S1 in FIG. 4, or may be formed in step S4. In the case in which the electrode 20b is formed in step S4, a third ceramic plate having holes formed at the same positions as the second hole 23a of the second ceramic plate 23 is prepared in step S1. A conductive paste is applied onto the third ceramic plate, and the second ceramic plate 23 is stacked on the third ceramic plate in step S3. When firing is performed in step S4, an electrostatic chuck 20 having an electrode 20b under the flow path 22a can be obtained. When the electrode 20b is provided on the flow path 22a, a ceramic plate having holes formed at the same positions as the first holes 21a of the first ceramic plate 21 is prepared as the third ceramic plate, and the same procedure may be performed. However, since the diameter of each first hole 21a is smaller than that of the second hole 23a and the number of first holes 21a is larger than that of the second hole 23a, precise positional alignment is required. Therefore, it is preferable to form the electrode 20b under the flow path 22a.

[Flow Path within Electrode]

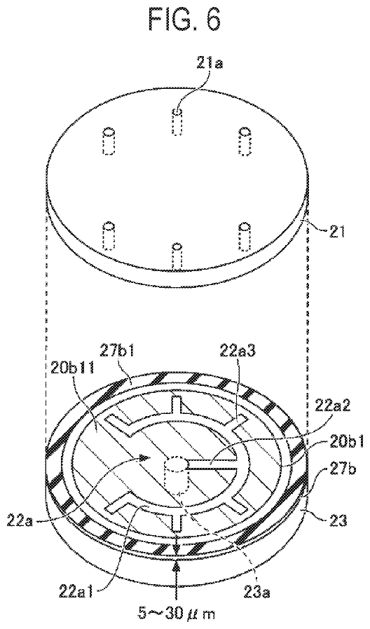

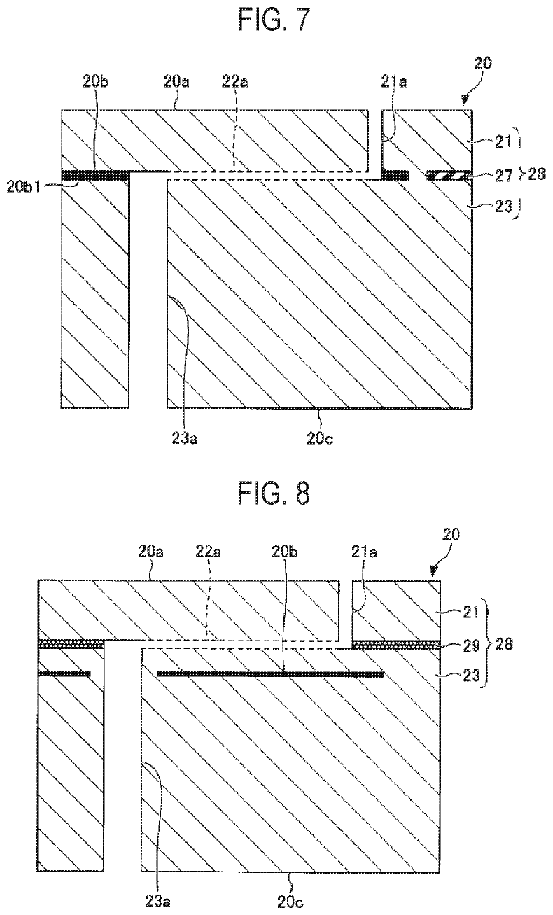

In the method of manufacturing the electrostatic chuck 20 according to an embodiment, a flow path may be formed in the electrode 20b. That is, the electrode 20b illustrated in FIG. 3 may be formed by a slurry layer. FIG. 6 is a view for explaining another example of the method of manufacturing the electrostatic chuck 20 according to an embodiment. FIG. 7 is a view illustrating another example of a cross section taken along line A-A in FIG. 2.

Here, instead of the dielectric slurry layer 22 illustrated in FIG. 5B, a conductive slurry layer 20b1 made of a conductive material illustrated in FIG. 6 is formed on the second ceramic plate 23. In this case, as illustrated in FIG. 7, which shows another example of across section taken along line A-A in FIG. 2, the electrode 20b illustrated in FIG. 1 is formed by the conductive slurry layer 20b1, and a flow path 22a is formed inside the conductive slurry layer 20b1. The flow path 22a has the flow paths 22a1 to 22a3 similarly to the flow path 22a shown in FIG. 5B, and thus the description thereof will be omitted here. The shape of the flow path 22a is not limited to the examples illustrated in FIGS. 5B and 6, and the first holes 21a and the second hole 23a can be connected to each other. Any configuration may be used as long as the first holes 21a and the second hole 23a are formed at different positions in the horizontal direction.

The slurry 20b11 (see FIG. 6) applied to form the conductive slurry layer 20b1 to be used as the electrode 20b of FIG. 7 is obtained by mixing (dispersing) conductive powder with a solvent. The solvent is a fluorine-based or phenol-based solution, and the conductive powder is mixed with this solution. The conductive powder may be any of tungsten carbide (WC), molybdenum carbide (MoC), and tantalum carbide (TaC).

When the conductive slurry layer 20b1 is exposed from the space between the first ceramic plate 21 and the second ceramic plate 23, the conductive material is exposed to plasma and causes metal contamination inside the processing container 10. Therefore, as illustrated in FIG. 6, the slurry 20b11 forming the conductive slurry layer 20b1 is applied in a circular shape inward of the second ceramic plate 23, and a slurry 27b1 that forms a dielectric slurry layer 27b is applied to cover the outer periphery of the slurry 20b11 by leaving a gap with the slurry 20b11. The conductive slurry layer 20b1 and the dielectric slurry layer 27b are formed by screen printing. As an example, the dielectric slurry layer 27b may be formed by applying the conductive slurry 20b11 in a state in which portions corresponding to the dielectric slurry layer 27b and the gap are masked, and then applying the dielectric slurry 27b1 in a state in which portions corresponding to the conductive slurry layer 20b1 and the gap are masked.

In this manner, between the first ceramic plate 21 and the second ceramic plate 23, the conductive slurry layer 20b1 including the flow path 22a having a thickness of about 5 μm to 30 μm and the dielectric slurry layer 27b are formed with a gap therebetween. By providing the gap, it is possible to prevent the conductive slurry layer 20b1 and the dielectric slurry layer 27b from being mixed with each other. After forming the conductive slurry layer 26b1 and the dielectric slurry layer 27b, the first ceramic plate 21, the conductive slurry layer 26b1 and the dielectric slurry layer 27b, and the second ceramic plate 23 are stacked one above another and fired while being pressurized. At this time, the first ceramic plate 21 and the second ceramic plate 23, which were tired in advance, have some degree of strength. Therefore, even if pressure is applied to the first ceramic plate 21 and the second ceramic plate 23, deformation does not occur in the first ceramic plate 21 and the second ceramic plate 23. Thus, it is possible to press and solidify the first ceramic plate 21 and the second ceramic plate 23 in the vertical direction. As a result, the first ceramic plate 21 and the second ceramic plate 23 are integrated with the conductive slurry layer 20b1 and the dielectric slurry layer 27b, so that the electrode 20b and the dielectric layer 27 illustrated in FIG. 7 are formed. Thus, it is possible to form the flow path 22a having a thickness of about 5 μm to 30 μm inside the conductive member (the electrode 20b). Even in such a case, the flow path 22a can be connected to the first holes 21a and the second hole 23a so as to make the heat transfer gas flow therethrough. Since the dielectric layer 27 covers the electrode 20b, it is possible to prevent the electrode 20b from being exposed to plasma and causing metal contamination.

### [Porous Flow Path]

In the method of manufacturing the electrostatic chuck 20 according to an embodiment, it is possible to form the slurry layer 22, the conductive slurry layer 20b1, and the dielectric slurry layer 27b as porous layers having the flow path 22a by firing the layers by the following method.

For example, the slurry layers are unlikely to be formed in a porous shape when the temperature is controlled to be constant at 1,200 degrees C. to 1,700 degrees C. during firing. In contrast, it is possible to form the slurry layers in a porous shape by controlling the initial temperature at the time of firing to 700 degrees C. to 800 degrees C. and controlling the temperature to 1,200 degrees C. to 1,700 degrees C. after a predetermined period of time. In addition, the slurry layers may be formed in a porous shape by changing a ratio of the slurry powder to the solvent, or the porosity of the porous shape may be changed.

FIG. 8 is a view illustrating another example of a cross section taken along line A-A in FIG. 2. By forming a porous layer 29 having a flow path 22a, a portion of the side surface of the ceramic plate 28 has a porous shape, as illustrated in FIG. 8. When a heat transfer gas such as a helium gas is caused to flow through the flow path 22a, the heat transfer gas enters the pores in the porous layer 29 from the flow path 22a, and leaks from the side surface of the ceramic plate 28. As a result, it is possible to prevent reaction products from adhering to the side surface of the electrostatic chuck 20.

### [Remanufacturing of Electrostatic Chuck]

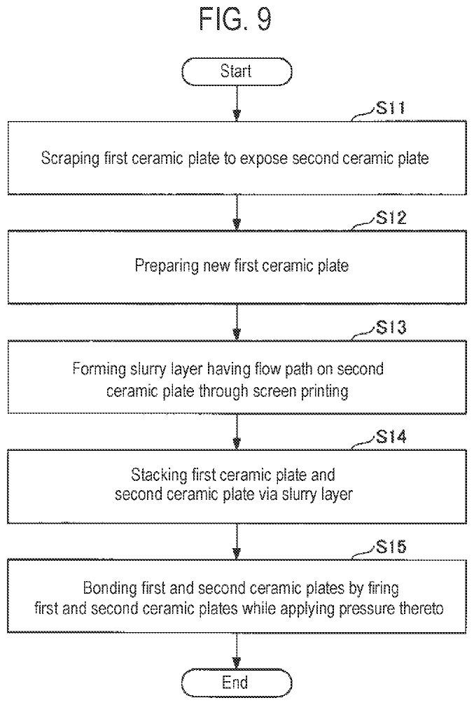

Next, an electrostatic chuck manufacturing method according to an embodiment for reuse will be described with reference to FIG. 9. FIG. 9 is a flowchart illustrating an example of the electrostatic chuck manufacturing method according to an embodiment for reuse.

When the process of FIG. 9 is started, the first ceramic plate 21 is scraped to expose the second ceramic plate 23 (step S1). Subsequently, a new first ceramic plate 21 having the first holes 21a is prepared (step S12).

Subsequently, a slurry layer 22, in which a flow path 22a connecting the first holes 21a and the second hole 23a is formed, is formed on the second ceramic plate 23 through screen printing (step S13). The slurry layer 22 may be formed on the new first ceramic plate 21.

Subsequently, the new first ceramic plate 21 and the second ceramic plate 23 are stacked one above the other via the slurry layer 22 (step S14). Subsequently, the slurry layer 22 is fired so as to bond the new first ceramic plate 21 and the second ceramic plate 23 to each other, thereby remanufacturing the electrostatic chuck 20 (step S15). Then, the process is completed.

By executing the electrostatic chuck manufacturing method according to the embodiment by replacing the first ceramic plate 21 exposed to plasma with the new one in this manner, it is possible to reuse an electrostatic chuck capable of preventing abnormal discharge.

The slurry layers used in the electrostatic chuck manufacturing method of the present embodiment are not limited to the slurry layers in which given powder is dispersed in a fluorine-based or phenol-based solution. For example, the slurry layers used in the electrostatic chuck manufacturing method of the present embodiment may be produced by adding a predetermined amount of a solution, a sintering aid, and a binder to given powder, and grinding a mixture obtained thus until the mixture has a predetermined particle size. As the sintering aid to be added, a B₄C-based or rare earth oxide-Al₂O₃-based sintering aid may be used. In addition, the binder to be added may be a synthetic resin. For example, as the binder, rosin ester, ethyl cellulose, ethyl hydroxyethyl cellulose, butyral resin, phenol resin, polyethylene oxide-based resin, poly (2-ethyloxazoline)-based resin, or polyvinylpyrrolidone-based resin may be used. The binder may be a polyacrylic acid-based resin, a polymethacrylic acid-based resin, a polyvinyl alcohol-based resin, an acrylic resin, a polyvinyl butyral resin, an alkyd resin, polybenzyl, poly(m-divinylbenzene), polystyrene, or the like.

As described above, according to the present embodiment, it is possible to provide the electrostatic chuck manufacturing method, the electrostatic chuck, and the substrate processing apparatus, which are capable of preventing abnormal discharge. In addition, according to the electrostatic chuck manufacturing method of the present embodiment, it is possible to reuse the electrostatic chuck 20 capable of preventing abnormal discharge.

According to an aspect, it is possible to provide an electrostatic chuck manufacturing method, an electrostatic chuck, and a substrate processing apparatus, which are capable of preventing abnormal discharge.

It should be noted that the electrostatic chuck manufacturing method, the electrostatic chuck, and the substrate processing apparatus according to the embodiments disclosed herein are exemplary in all respects and are not restrictive. The above-described embodiments may be omitted, replaced or modified in various forms without departing from the scope and spirit of the appended claims. The matters described in the above-described embodiments may be implemented in another configuration to the extent they are not inconsistent, or may be combined to the extent they are not inconsistent.

For example, in the example of FIG. 3, the electrode 20b and the flow path 22a are provided only under the placement surface 20a on which the substrate W is placed, but the electrode 20b and the flow path 22a may also be provided under the stepped portion on which the edge ring 25 is placed.

The substrate processing apparatus of the present disclosure is applicable to any of an atomic layer deposition (ALD) type apparatus, a capacitively coupled plasma (CCP) type apparatus, an inductively coupled plasma (ICP) type apparatus, a radial line slot antenna (RLSA) type apparatus, an electron cyclotron resonance plasma (ECRP) type apparatus, and a helicon wave plasma (HWP) type apparatus.

In addition, a plasma processing apparatus has been described as an example of the substrate processing apparatus. However, the substrate processing apparatus is not limited to the plasma processing apparatus, and may be any apparatus as long as it performs a predetermined processing (e.g., a film forming process, an etching process, or the like) on a substrate.

What is claimed is:

1. A method of manufacturing an electrostatic chuck, the method comprising:
preparing a first ceramic plate having a first hole formed therein;
preparing a second ceramic plate having a second hole formed at a position different from a position of the first hole in a horizontal direction:
forming a first slurry layer on the first ceramic plate or the second ceramic plate with a first slurry, the first slurry layer having a flow path formed therein to connect the first hole and the second hole;
stacking the first ceramic plate and the second ceramic plate one above the other via the first slurry layer; and
bonding the first ceramic plate and the second ceramic plate stacked one above the other via the first slurry layer.

2. The method of claim 1, wherein the first ceramic plate and the second ceramic plate are a sintered body of aluminum oxide, or a sintered body of aluminum oxide to which silicon carbide is added.

3. The method of claim 1, wherein the first slurry is formed by mixing aluminum oxide powder or aluminum oxide powder to which silicon carbide is added with a solvent.

4. The method of claim 1, wherein the first ceramic plate or the second ceramic plate includes an electrode.

5. The method of claim 1, wherein the first slurry is formed by mixing conductive powder with a solvent.

6. The method of claim 5, wherein the conductive powder is any one of tungsten carbide, molybdenum carbide, and tantalum carbide.

7. The method of claim 1, wherein the slurry layer is formed by screen printing.

8. The method of claim 1, wherein the flow path includes a main flow path and a sub-flow path connected to the main flow path and having a width narrower than a width of the main flow path.

9. The method of claim 8, wherein the main flow path is configured to be connected to the second hole, and the sub-flow path is configured to be connected to the first hole.

10. The method of claim 1, wherein an opening of the first hole is smaller than an opening of the second hole.

11. The method of claim 1, wherein the flow path has a height of 5 μm to 30 μm.

12. The method of claim 1, further comprising:
scraping the first ceramic plate to expose the second ceramic plate;
preparing a new first ceramic plate having a new first hole;
forming a second slurry layer on the new first ceramic plate or the second ceramic plate with a second slurry, the second slurry layer having a new flow path formed therein to connect the new first hole and the second hole;
stacking the new first ceramic plate and the second ceramic plate one above the other via the second slurry layer; and
remanufacturing the electrostatic chuck by bonding the new first ceramic plate and the second ceramic plate stacked one above the other via the second slurry layer.

13. An electrostatic chuck comprising a ceramic plate, wherein the ceramic plate includes:
a first hole formed in a top surface of the ceramic plate;
a second hole formed at a position different from a position of the first hole in a horizontal direction; and
a flow path formed inside the ceramic plate to connect the first hole and the second hole.

14. The electrostatic chuck of claim 13, wherein the flow path is formed by a conductive member.

15. The electrostatic chuck of claim 13, wherein the flow path is formed in a porous shape.

16. The electrostatic chuck of claim 13, wherein the flow path includes a main flow path and a sub-flow path connected to the main flow path and having a width narrower than a width of the main flow path, and
the main flow path is connected to the second hole, and the sub-flow path is connected to the first hole.

17. The electrostatic chuck of claim 13, wherein an opening of the first hole is smaller than an opening of the second hole.

18. A substrate processing apparatus comprising:
a processing container;
a stage disposed inside the processing container and configured to place a substrate thereon; and
an electrostatic chuck provided on the stage and having a ceramic plate configured to hold the substrate on a top surface of the ceramic plate,
wherein the electrostatic chuck includes:
a first hole formed in the top surface of the ceramic plate,
a second hole formed in a bottom surface of the ceramic plate at a position different from a position of the first hole in a horizontal position, and
a flow path formed inside the ceramic plate to connect the first hole and the second hole.

19. The substrate processing apparatus of claim 18, wherein the second hole is connected to a gas source via a gas supply line.

20. The substrate processing apparatus of claim 18, wherein the flow path is formed in a porous shape.
